(19) United States
(12) Patent Application Publication
(10) Pub. No.: US 2025/0204276 A1
(43) Pub. Date: Jun. 19, 2025

(54) QUANTUM COMPUTING DEVICE WITH DISCRETE JOSEPHSON JUNCTIONS

(71) Applicant: INTERNATIONAL BUSINESS MACHINES CORPORATION, ARMONK, NY (US)

(72) Inventors: Elbert Emin Huang, Mountain View, CA (US); Charles Thomas Rettner, San Jose, CA (US)

(21) Appl. No.: 18/389,696

(22) Filed: Dec. 19, 2023

(51) Int. Cl. H10N 60/12; G06N 10/40; H10N 60/01; H10N 60/80

(52) U.S. Cl. CPC H10N 60/12; G06N 10/40; H10N 60/0912; H10N 60/805

(57) ABSTRACT

A device includes a first superconducting layer over a substrate, a first insulating barrier over the first superconducting layer, a second superconducting layer formed over the first insulating barrier, a second insulating barrier over the second superconducting layer, and a third superconducting layer formed over the second insulating barrier. The first, second, and third superconducting layers are formed via a first, second and third angled depositions, respectively.

### BACKGROUND

The present disclosure generally relates to quantum computing devices, and more particularly, to quantum computing devices with discrete Josephson junction structures, and methods of creation thereof.

In quantum devices, such as superconducting qubits, Josephson junctions are salient components that exhibit quantum mechanical effects. A Josephson junction is a device made up of two superconductors separated by a thin insulating layer. When cooled to extremely low temperatures, the superconductors can exhibit quantum mechanical effects that allow electric current to flow through the insulating layer without resistance, which can be used in various applications.

### SUMMARY

According to an embodiment, a device includes a first superconducting layer over a substrate, a first insulating barrier over the first superconducting layer, a second superconducting layer over the first insulating barrier, a second insulating barrier over the second superconducting layer, and a third superconducting layer over the second insulating barrier.

In some embodiments, which can be combined with the previous embodiment, the first insulating barrier and the second insulating barrier have different thicknesses.

In some embodiments, which can be combined with one or more previous embodiments, the device includes a plurality of Josephson junctions with more than one resistance area products.

In some embodiments, which can be combined with one or more previous embodiments, at least one of the first, second, and third superconducting layers includes aluminum.

In some embodiments, which can be combined with one or more previous embodiments, the first, second and third superconducting layers comprise a same material.

In some embodiments, which can be combined with one or more previous embodiments, at least two of the first, second, and third superconducting layers comprise different materials.

According to another embodiment, a method of fabricating Josephson junctions includes forming one or more resist layers over a substrate, patterning the one or more resist layers to define openings for forming the Josephson junctions forming a first superconducting layer via a first angled deposition, forming a first insulation barrier over the first superconducting layer, forming a second superconducting layer via a second angled deposition, forming a second insulating barrier over the second superconducting layer, and forming a third superconducting layer via a third angled deposition.

In some embodiments, which can be combined with the previous embodiment, the first and second insulating barriers have different thicknesses.

In some embodiments, which can be combined with one or more previous embodiments, the first, second and third angled depositions are performed through a portion of the openings.

In some embodiments, which can be combined with one or more previous embodiments, the method further includes fabricating the Josephson junctions with the first and second insulating barriers that have more than one target resistance area based on at least one of: patterns of the defined openings, a formation of the first and second insulating barriers, and a direction of each of the first, second and third superconducting layers.

In some embodiments, which can be combined with one or more previous embodiments, at least one of the first, second or third the superconducting layers includes aluminum.

In some embodiments, which can be combined with one or more previous embodiments, at least one of the first, second, or third superconducting layers is formed by an electron beam evaporation technique.

In some embodiments, which can be combined with one or more previous embodiments, forming each of the first and second insulating barriers includes exposure to a pre-determined partial pressure of oxygen gas for a pre-determined time. The pre-determined time is used to form the insulating barrier with target thicknesses.

In some embodiments, which can be combined with one or more previous embodiments, forming the first and second insulating barriers further includes oxidizing at least one of the first or second superconducting layers.

In some embodiments, which can be combined with one or more previous embodiments, forming the first and second insulating barriers further includes nitriding at least one of the first or second superconducting layers.

In some embodiments, which can be combined with one or more previous embodiments, forming the first and second insulating barriers further includes exposing at least one of the first or second superconducting layers to a reactive gas.

In some embodiments, which can be combined with one or more previous embodiments, forming the first and second insulating barriers involves the deposition of a dielectric material including but not limited to aluminum oxide, aluminum nitride, silicon oxide, silicon nitride, silicon, and magnesium oxide.

In some embodiments, which can be combined with one or more previous embodiments, the first, second and third superconducting layers are constructed of a same material.

In some embodiments, which can be combined with one or more previous embodiments, at least two of the first, second and third superconducting layers are constructed of different materials.

According to yet another embodiment, a method for forming Josephson junctions includes forming one or more resist layers over a substrate, patterning the one or more layers to define openings for forming the Josephson junctions, forming a first superconducting layer via a first angled deposition, forming a second superconducting layer via a second angled deposition, forming a third superconducting layer via a third angled deposition, and forming insulating barriers on at least the first or second superconducting layers. The insulating barriers have different thicknesses.

In some embodiments, which can be combined with the previous embodiment, forming the insulating barrier is performed based on at least one of: i) oxidizing at least one of the first or second superconducting layers, ii) nitriding at least one of the first or second superconducting layers, and iii) exposing of at least one of the first or second superconducting layers to a reactive gas.

In another aspect, a method for forming Josephson junctions includes forming one or more resist layers, patterning the one or more resist layers to define openings for forming the Josephson junctions, forming a first superconducting layer, forming a second superconducting layer, forming a third superconducting layer; and forming insulating barriers on at least the first or second superconducting layers. The first, second and third superconducting layers are formed in one vacuum step fabrication process.

In some embodiments, which can be combined with the previous embodiment, the method includes fabricating the Josephson junctions with the insulating barriers that have more than one target resistance area based on at least one of: patterns of the defined openings, a formation of the insulating barriers, or a direction of each of the first, second and third superconducting layers.

In some embodiments, which can be combined with one or more previous embodiments, forming the insulating barriers further comprises oxidizing the first and second superconducting layers.

In some embodiments, which can be combined with one or more previous embodiments, forming the insulating barriers further comprises nitriding the first and second superconducting layers.

In some embodiments, which can be combined with one or more previous embodiments, forming the insulating barriers further comprises exposing the first and second superconducting layers to a reactive gas.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1E illustrate the process of making a Josephson junction using the Manhattan approach.

FIGS. 2A-2E illustrate the process of making a Josephson junction using the Dolan bridge approach.

FIGS. 3A-3B illustrate the quantum computing device with discrete Josephson junctions fabricated based on Manhattan approach, in accordance with some embodiments.

FIGS. 4A-4B illustrate the quantum computing device with discrete Josephson junctions fabricated based on Dolan bridge approach, in accordance with some embodiments.

FIGS. 5A-5C illustrate the process of making two Josephson junctions in a single vacuum step with three depositions based on a Manhattan-Manhattan approach, in accordance with some embodiments.

FIGS. 6A-6C illustrate the process of making two Josephson junctions in a single vacuum step with three depositions based on a Manhattan-Dolan approach, in accordance with some embodiments.

FIGS. 7A-7F illustrate the process of making two sets of Josephson junctions with three depositions based on a Dolan-Dolan approach, in accordance with some embodiments.

FIGS. 8A-8C illustrate the process of making three Josephson junctions in a single vacuum step, in accordance with some embodiments.

FIGS. 9A-9C illustrate the process of making three Josephson junctions in a single vacuum step, in accordance with some embodiments.

FIGS. 10A-10C illustrate the processes for fabricating four discrete junctions, in accordance with some embodiments.

FIGS. 11A-11C illustrate exemplary demonstration images of fabricated Josephson junctions, in accordance with some embodiments.

FIG. 12 illustrates a block diagram of a method for forming the quantum computing device with discrete Josephson junctions, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “over, “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of an element.

As used herein, the term “vertical” describes an orientation that is arranged perpendicular to the first surface of an element.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

According to an embodiment, a device includes a first superconducting layer over a substrate, a second superconducting layer formed over the first superconducting layer, a third superconducting layer formed over the second superconducting layer, and insulating barriers on at least two of the first or second superconducting layers. The superconducting layers are deposited in a single-step vacuum deposition, enabling fabricating more than one Josephson junctions at a single step.

In some embodiments, which can be combined with the previous embodiment, the one or more insulating barriers have different thickness of the barriers relates directly to the resistance area product of the corresponding Josephson junctions, and thus to device frequencies. The different thicknesses therefore correspond to Josephson junctions with different resistance area products, allowing the creation of devices with the same or different frequencies, independent of the area of the Josephson junctions.

In some embodiments, which can be combined with one or more previous embodiments, the device includes a plurality of Josephson junctions with more than one resistance area products. Thus, multiple Josephson junctions with different properties can be obtained in a single step fabrication process.

In some embodiments, which can be combined with one or more previous embodiments, at least one of the first, second, and third superconducting layers includes aluminum. By virtue of using Aluminum, process complexity is reduced.

In some embodiments, which can be combined with one or more previous embodiments, the first, second and third superconducting layers are constructed of a same material. Thus, multiple Josephson junctions with various properties can be obtained in a single step fabrication process and via by using a single material.

In some embodiments, which can be combined with one or more previous embodiments, at least two of the first, second, and third superconducting layers are constructed of different materials. Thus, multiple Josephson junctions with various properties can be obtained in a single step fabrication process. The ability to use different materials can increase fabrication options of the Josephson junctions.

According to another embodiment, a method of fabricating Josephson junctions includes forming one or more resist layers over a substrate, patterning the one or more resist layers to define openings for forming the Josephson junctions forming a first superconducting layer via a first angled deposition, forming a first insulating barrier over the first superconducting layer, forming a second superconducting layer via a second angled deposition, forming a second insulating barrier over the second superconducting layer, and forming a third superconducting layer via a third angled deposition. The first, second and third angled deposition are performed at different azimuthal angles. The superconducting layers are deposited in a single-step vacuum deposition, enabling fabricating more than one Josephson junctions at a single step.

In some embodiments, which can be combined with the previous embodiment, the first and second insulating barriers have different thicknesses. Thus, various barrier properties can be obtained.

In some embodiments, which can be combined with one or more previous embodiments, the first, second and third angled depositions are performed through a portion of the openings. As such, only a portion of the device is used for fabrication.

In some embodiments, which can be combined with one or more previous embodiments, the method further includes fabricating the Josephson junctions with the first and second insulating barriers that have more than one target resistance area product based on at least one of: patterns of the defined openings, a formation of the first and second insulating barriers, and a direction of each of the first, second and third superconducting layers. Thus, multiple Josephson junctions with various properties can be obtained in a single step fabrication process.

In some embodiments, which can be combined with one or more previous embodiments, at least one of the first, second or third the superconducting layers includes aluminum. Aluminum is widely used as the material in Josephson junctions.

In some embodiments, which can be combined with one or more previous embodiments, at least one of the first, second, or third superconducting layers is formed by an electron beam evaporation technique. Electron beam evaporation can provide accurate deposition of materials.

In some embodiments, which can be combined with one or more previous embodiments, forming each of the first and second insulating barriers includes exposure to a pre-determined partial pressure of oxygen gas for a pre-determined time. The pre-determined time is used to form the insulating barrier with target thicknesses. Thus, multiple junctions with different barrier properties can be fabricated.

In some embodiments, which can be combined with one or more previous embodiments, forming the first and second insulating barriers further includes oxidizing at least one of the first or second superconducting layers. The oxidation provides the insulating barrier by forming an insulating oxide.

In some embodiments, which can be combined with one or more previous embodiments, forming the first and second insulating barriers further includes nitriding at least one of the first or second superconducting layers. Nitriding can also provide the insulating barrier by forming a nitride.

In some embodiments, which can be combined with one or more previous embodiments, forming the first and second insulating barriers further includes exposing the first and second superconducting layers to a reactive gas. Exposing to gas can further provide the insulating barrier.

In some embodiments, which can be combined with one or more previous embodiments, the first, second and third superconducting layers are constructed of a same material. Thus, multiple Josephson junctions with various properties can be obtained in a single step fabrication process and via a single material.

In some embodiments, which can be combined with one or more previous embodiments, at least two of the first, second and third superconducting layers are constructed of different materials. Thus, multiple Josephson junctions with various properties can be obtained in a single step fabrication process. The ability to use different materials can increase the tunability of the Josephson junctions.

According to an embodiment, a method for forming Josephson junctions includes forming one or more resist layers over a substrate, patterning the one or more layers to define openings for forming the Josephson junctions, forming a first superconducting layer via a first angled deposition, forming a second superconducting layer via a second angled deposition, forming a third superconducting layer via a third angled deposition, and forming insulating barriers on at least the first or second superconducting layers. The insulating barriers have different thicknesses. The superconducting layers are deposited in a single-step vacuum deposition, enabling fabricating more than one Josephson junction at a single step.

In some embodiments, which can be combined with the previous embodiment, forming the insulating barriers is performed based on at least one of: i) oxidizing the first and second superconducting layers, ii) nitriding the first and second superconducting layers, and iii) exposing the first and second superconducting layers to a reactive gas. The insulating barriers can be fabricated by either oxidizing the superconducting layers, nitriding the superconducting layers, or exposing the conducting materials to an alternative reactive gas.

According to another embodiment, a method for forming Josephson junctions includes forming one or more resist layers, patterning the one or more resist layers to define openings for forming the Josephson junctions, forming a first superconducting layer, forming a second superconducting layer, forming a third superconducting layer; and forming insulating barriers on at least one of the first or second superconducting layers. The first, second and third superconducting layers are formed in one vacuum step fabrication process. The superconducting layers are deposited in a single-step vacuum deposition, enabling fabricating more than one Josephson junctions at a single step.

In some embodiments, which can be combined with the previous embodiment, the method includes fabricating the Josephson junctions with the insulating barriers that have more than one target resistance area products based on at least one of: patterns of the defined openings, a formation of the insulating barriers, or a direction of each of the first, second and third superconducting layers. Thus, multiple Josephson junctions with various properties can be obtained in a single step fabrication process.

In some embodiments, which can be combined with one or more previous embodiments, forming the insulating barriers further comprises oxidizing at least one of the first or second superconducting layers. The oxidation can provide the insulating barrier.

In some embodiments, which can be combined with one or more previous embodiments, forming the insulating barriers further comprises nitriding the first and second superconducting layers. The nitriding can also provide the insulating barrier.

In some embodiments, which can be combined with one or more previous embodiments, forming the insulating barriers further comprises exposing the first and second superconducting layers to a reactive gas. The exposure to a reactive gas can further provide the insulating barrier.

The concepts herein relate to Josephson junctions, which are devices made up of two superconductors separated by a thin insulating layer. When cooled to extremely low temperatures, the superconductors can exhibit quantum mechanical effects that allow electric current to flow.

For certain quantum device layouts and designs, it may be necessary to have Josephson junctions with more than one target junction resistance value. Currently, one way to achieve different junction resistances would be to fabricate the junctions with different physical areas. Larger junctions would have lower resistance, while smaller junctions would have higher resistance. However, this approach has significant drawbacks. To achieve a very low resistance, the required junction area may end up considerably larger than the optimal size afforded by yield and coherence considerations. On one hand, smaller junctions are typically more difficult to fabricate reliably with high yields. On the other hand, larger junction areas mean more defects present in the insulating barrier, which can degrade the junction's quantum coherent properties. Therefore, it may not be feasible, or desirable, to create multiple different junction resistances by only changing the junction areas. Moreover, the resulting Josephson junctions may be impractical to fabricate or fail to meet the necessary performance specifications.

An alternative approach is to pattern and deposit the Josephson junction in two separate fabrication steps, creating Josephson junctions with the same or very similar sizes but with different insulating barrier properties, e.g., different thicknesses. However, this approach requires the first deposited Josephson junctions to undergo additional processing steps such as high-temperature baking. These steps can negatively impact the junction performance. The extra processing also increases fabrication time and cost, and may reduce yields.

Thus, although creating Josephson junctions with varying resistances is necessary for certain quantum devices, conventional approaches have significant drawbacks. The present disclosure is directed to fabrication strategies to produce tunable Josephson junction resistances while maintaining high performance, yield, and efficiency.

To tackle the above-mentioned, and other, problems, disclosed is a quantum computing device that utilizes standard Josephson junction fabrication processes in a way that enables forming multiple discrete sets of Josephson junctions, with two or more junctions per set, in a single patterning and deposition sequence. Such discrete Josephson junctions are fabricated with only one vacuum processing step. By creatively leveraging resist patterning, deposition angles, substrate rotation, and conventional Josephson junction fabrication steps, this disclosure provides a way to obtain multiple junctions sets with varying resistances in a single vacuum process, which improves efficiency while meeting the needs of complex quantum device designs.

In an aspect of the present disclosure, the Josephson junctions in each discrete set can be made with the same or different barrier areas, but with different barrier properties, e.g., different oxide thicknesses. This allows creating junctions with varying resistances as needed by a quantum device design, overcoming limitations of conventional fabrication approaches.

In another aspect, the disclosed deposition/barrier formation sequence includes at least three deposition steps, each separated by a barrier formation step such as oxidation or nitridation. Furthermore, the present disclosure utilizes a predetermined deposition approach tailored by selecting the deposition angle (0) and azimuthal substrate rotational angle (+) appropriately. By judiciously choosing these angles, resist thicknesses, and standard Josephson junction parameters such as metal thickness and oxidation conditions, the Josephson junctions in each set can be formed with more than one target resistance in a single processing sequence.

Accordingly, the teachings herein provide methods and systems for fabricating Josephson junctions and their structures. The techniques described herein may be implemented in a number of ways. Example implementations are provided below with reference to the following figures.

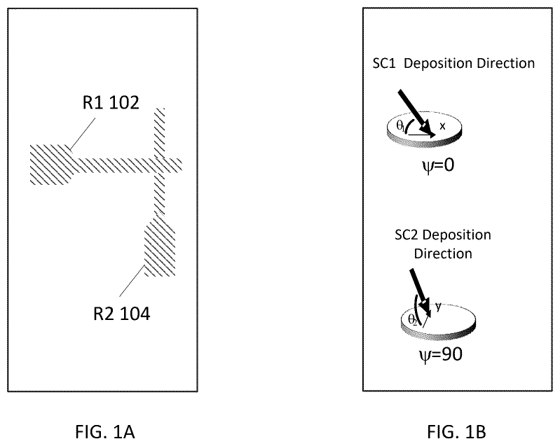

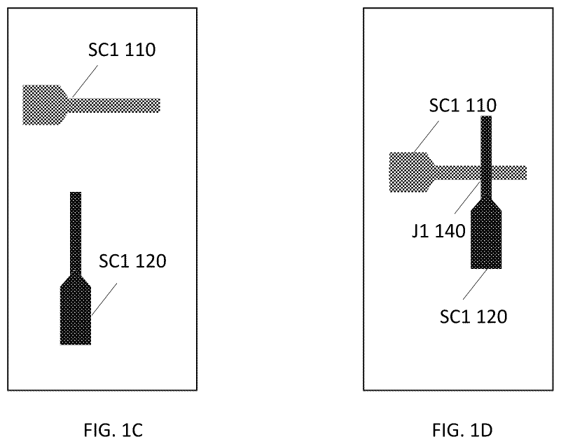

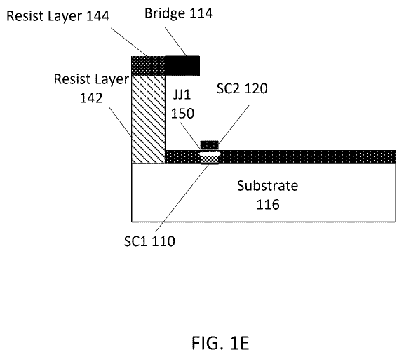

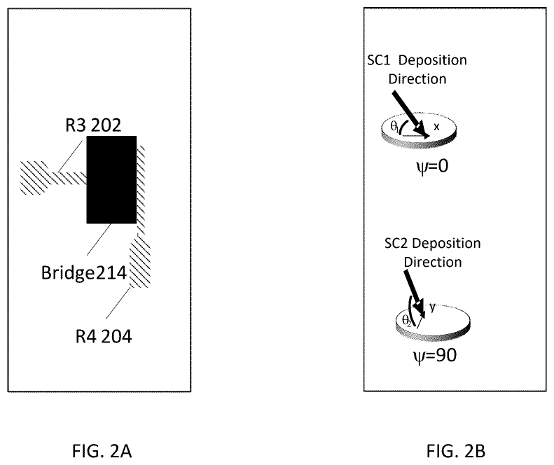

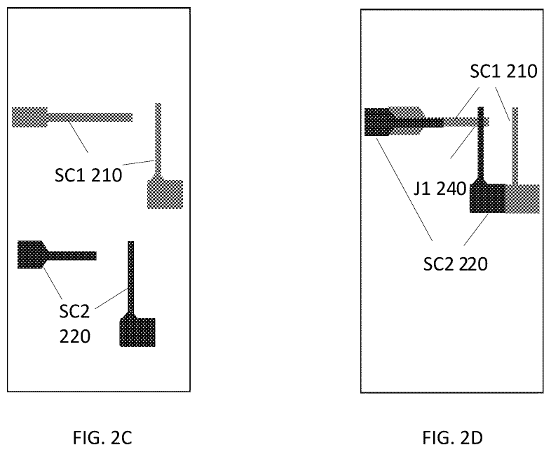

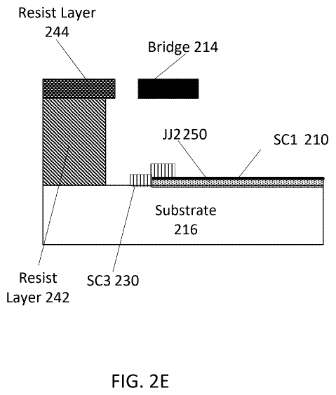

Reference is now made to FIGS. 1 and 2, which are schematic illustrations of the conventional process of fabricating a Josephson junction using two different approaches. Josephson junctions are commonly fabricated using a double-angle evaporation technique where superconducting layer, hereinafter “SC,” most commonly aluminum, is deposited using a lithography mask. A tunnel barrier of the junctions is formed by oxidation of the first of two metal layers. The junctions are completed by the second deposition at a second angle chosen to form a second “finger” that overlaps the first. The junctions are formed at the overlap. Two common approaches may be distinguished by the names “Manhattan” and “Dolan bridge.” FIGS. 1A-1D are schematic illustrations of the process of making a Josephson junction using the Manhattan approach. In Manhattan approach, a cross-shaped resist mask and alternating perpendicular depositions are used to define the overlapping Josephson junction structure in a single-layer fabrication process. Typically, the lithography mask includes two perpendicular channels etched in the resist layer on the substrate. The channels intersect to form a cross shape similar to the streets of Manhattan, hence the name.

Typically, two separate depositions of superconducting layers are performed, each at an angle tilted relative to the substrate plane. The first superconducting layer deposition is performed parallel to the first resist channel to form the first finger of the junction. The surface of the first superconducting layer finger is oxidized to form the insulating tunnel barrier. The substrate is then rotated azimuthally by 90 degrees. The second superconducting layer deposition is performed parallel to the second perpendicular resist channel, overlapping with the first finger to complete the junction. In some embodiments, the first superconductor layer deposition does not get deposited on the substrate in the second resist channel and the second superconductor layer does not get deposited on the substrate in the first resist channel as the dimensions of the channel are too narrow for a given resist height when depositing at a defined angle. Finally, excess superconducting layer in other areas is lifted off by removing the resist, leaving only the junction. The channels can be extended to connect the junction to other superconducting components. FIG. 1A illustrates an outline of the openings made in the resist layers, R1 102 and R2 104. The resist mask includes two perpendicular channels where resist is developed, i.e., the R1 102 and R2 104, and both depositions are made at a tilt angle to the surface such that the deposited material is limited to one channel at a time. These channels may be extended to a wider dimension that may connect to another superconducting feature (not shown). The first deposition, i.e., the deposition of SC1 110, is carried out parallel to the first resist channel and the sample rotated azimuthally by 90 degrees for the second deposition, i.e., the deposition of SC2 120. The tunnel barrier can be formed by oxidation of the surface of the finger formed by the first deposition. A liftoff process can be performed to remove the resist layers and any excess first superconducting layer and the second superconducting layer

FIG. 1B illustrates the angles used for depositions. As depicted, while the deposition of SC1 110 is carried out parallel to the first resist channel, for deposition of SC2 120, the sample rotated azimuthally by 90 degrees. FIG. 1C individually illustrates the shapes of the two fingers for the first layer of metal, SC1 110, being deposited at an azimuthal angle of zero. SC1 110 is then oxidized to form a barrier layer, and then the second layer of metal, SC2, 120 is deposited. Thus, the different deposition is performed on a different level. For example, once the deposition of SC1 110 is performed and the barrier is formed, the deposition of SC2 120 takes place on a higher plane. FIG. 1D illustrates the final structure of the device. The Josephson junction is formed in the area where the two layers, i.e., SC1 110 and SC2 120, cross, i.e., J1 140. It should be noted that, in this context, parallel corresponds to when the direction of the first deposition projected onto the plane of the substrate coincides with the orientation of the first resist channel. FIG. 1E illustrates the process of making a Josephson junction using a Manhattan approach. The Josephson junction, JJ1 150, is formed where the SC1 110 and the SC2 120 cross, which is located below the bridge 114. The SC1 110 can be located over a substrate 116. A resist layer 142 is formed oved the substrate 116, and another resist layer 144 is formed over the resist layer 142. In some embodiments, the resist layer 144 can be made of a similar material as the bridge 114.

FIGS. 2A-2D are schematic illustrations of the process of making a Josephson junction using the Dolan bridge approach. In the Dolan bridge approach, a two-layer resist is used with a bridge to independently optimize the deposition angles and provide flexibility in forming the overlapping junction structure. The shadow mask includes two resist layers on the substrate. The lower resist layer has a cavity. A suspended bridge of the upper resist layer crosses over the lower layer cavity to create two openings. The first superconducting layer, SC1, 210 is deposited at an angle through one opening, forming the first finger. The first superconducting layer finger is oxidized to form the insulating tunnel barrier. The second superconducting layer, SC2, 220 is deposited through the other opening at a different azimuthal angle, which overlaps the first finger. The second angle is usually opposite the first, allowing the overlap, and the tilt angles can be optimized independently for yield and performance. The second finger overlaps the first finger on the substrate surface to complete the junction. Typically, the excess superconducting layer is lifted off by removing the resist layers after deposition. The bridge allows a two-layer resist process to define the junction.

FIG. 2A illustrates an outline of the opening made in the resist layers. This approach uses a bilayer resist. Each resist layer includes an opening, i.e., R3 202 and R4 204, such that a top resist opening R3 202 forms a bridge 214 over the bottom resist opening R4 204. A cavity is formed in the first resist layer that is directly on the substrate, and the bridge 214 is formed from the resist layer that is located on top of the first resist layer. In this example, the bridge 214 is defined by lithography but it can also be defined by selective dissolution undercutting the top resist in a bilayer resist. The superconducting layer, i.e., SC1 or SC2 shown in FIGS. 2B-2D, is then evaporated at a first angle and then at a second angle. The angles are chosen such that the material from the first deposition passing through a first opening is overlapped by the material from the second deposition passing through a second opening.

While FIG. 2A illustrates the common case of directing the second deposition opposite to the first deposition, the tilt angles are not necessarily the same and may be optimized for yield or performance. The second deposition often overlaps the first deposition at a place on the substrate. Similar to the Manhattan approach, the tunnel barrier is formed by the oxidation of the first of the two layers prior to the second deposition. A liftoff process can be performed to remove the excess resist layers.

FIG. 2B illustrates the angles used for depositions. As depicted, while the deposition of SC1 210 is carried out parallel to the first resist channel, for deposition of SC2 220, the sample rotated azimuthally by 180 degrees. FIG. 2C illustrates the outline of the individual shapes of the metal structures formed by each of the two depositions. The first layer, SC1, 210 is oxidized to form a barrier layer before the deposition of the second layer, SC2, 220, which in this case is deposited at an azimuthal angle of 180 degrees. FIG. 2D illustrates the final structure of the device. The Josephson junction is formed in the area where the two layers, SC1 210 and SC2 220, cross, i.e., J1 240.

FIG. 2E illustrates the process of making a Josephson junction using a Manhattan approach. The Josephson junction, JJ2 250 is formed where the SC1 210 and the SC3 230 cross, which is located below the bridge 214. The SC3 230 can be located over a substrate 216. A resist layer 242 is formed oved the substrate 216, and another resist layer 244 is formed over the resist layer 242. In some embodiments, the resist layer 244 can be made of a similar material as the bridge 214.

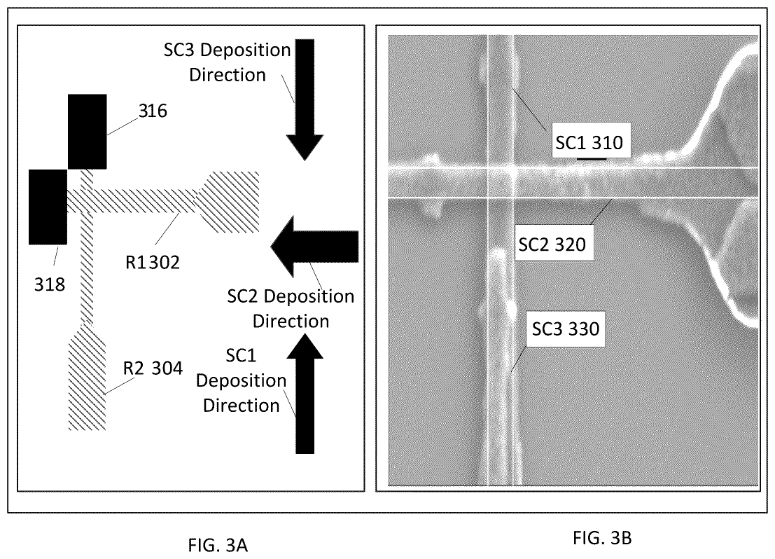

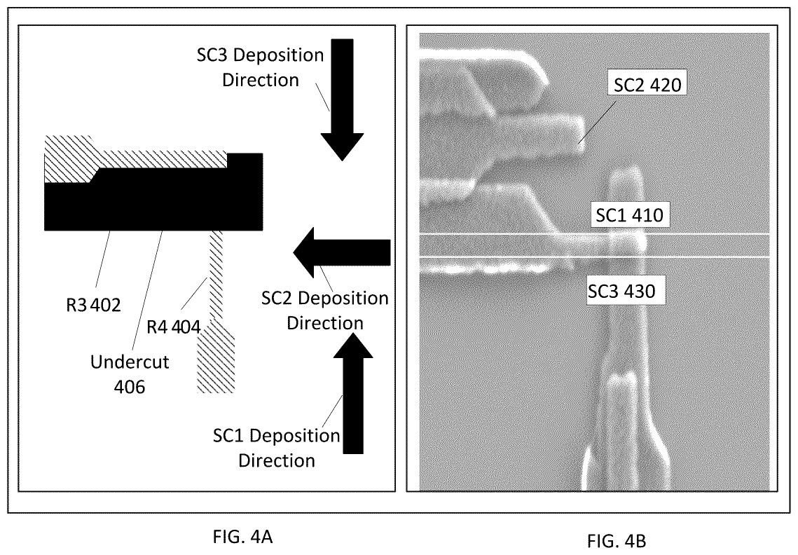

FIGS. 3A-3B and FIGS. 4A-4B illustrate simplified cross-section views of the quantum computing device with discrete Josephson junctions, in accordance with some embodiments. Referring to FIGS. 3A-3B now, in some embodiments, the quantum computing device with discrete Josephson junctions is fabricated using the Manhattan approach. The quantum computing device with discrete Josephson junctions includes a first resist opening, R1, 302 and a second resist opening R2, 304. The quantum computing device with discrete Josephson junctions has a shape that allows deposition of the first superconducting layer, SC1, 310 and the second superconducting layer, SC2, 320 but blocks the third superconducting layer, SC3, 330. In such a Josephson junction, the junction resistance is controlled by the oxidation that takes place after the deposition of SC1 310 and is not affected by the second oxidation. The areas 316 and 318 are undercut regions, where the bottom layer in the bilayer resist is removed, that aid in the lift off process. FIG. 3B shows a scanning electron micrograph of the resulting Josephson junction structure. SC1 310, SC2 320, and SC3 330 are shown by arrows. The Manhattan-style Josephson junction shown in FIG. 3B is formed in accordance with the process depicted in FIG. 3A.

Reference now is made to FIG. 4A, which illustrates a quantum computing device with discrete Josephson junctions fabricated using the Dolan approach. The quantum computing device with discrete Josephson junctions includes a first resist opening, R3, 402, a second resist opening, R4, 404, and an undercut region 406. The quantum computing device with discrete Josephson junctions has a shape that allows deposition of the first superconducting layer, SC1, 410 and the third superconducting layer, SC3, 430 but blocks the second superconducting layer, SC2, 420. In such a Josephson junction, the junction resistance is controlled by the sum of the oxidations after SC1 410 and after SC2 420. The undercut region 406, i.e., the rectangular area, is a region that is used to form the Dolan bridge. FIG. 4B shows a scanning electron micrograph of the resulting Josephson junction structure, showing SC1 410, SC2 420, and SC3 430. The Dolan-style Josephson junction shown in FIG. 4B is formed in accordance with the process depicted in FIG. 4A. It should be noted that, Josephson junctions can be formed at the overlap of the first and second angled deposition, the second and third angled deposition or the first and third angled deposition.

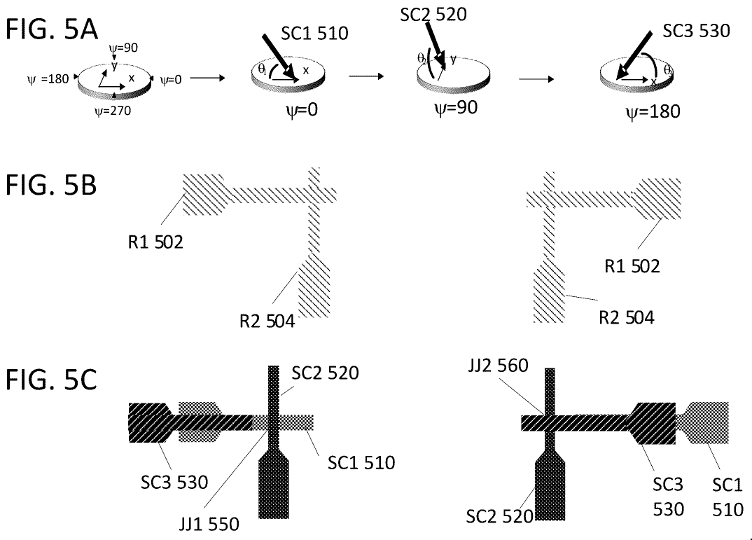

FIGS. 5A-5C illustrate the process of making two Josephson junctions in a single vacuum step with three depositions, in accordance with some embodiments. A pair of resist patterns is formed and deposition angles are selected to form two Manhattan-style junctions. FIG. 5A shows the sequence of angles used in this process. As shown, the deposition of SC1 510 is carried out parallel to the first resist channel, for deposition of SC2 520, the sample is rotated azimuthally by 90 degrees. For the third deposition, i.e., deposition of SC3 530, the sample is rotated another 90 degrees, thus 180 degrees compared to the first deposition. FIG. 5B depicts the outline of the openings made in the resist layers, i.e., R1 502 and R2 504. These two shapes are for junctions with potentially different oxidations steps and junction resistances. FIG. 5C illustrates a top view of the metal structures formed for the two resist openings at the two angles and is described in more detail below. The junctions are formed where the two superconducting layers cross, i.e., JJ1 550 is formed where SC1 510 and SC2 520 cross (as defined by the two resist openings R1 502 and R2 504) while JJ2 560 is formed where SC2 520 and SC3 530 cross (as defined by the two resist openings R1 502 and R2 504)

In some embodiments, multiple junctions with the same or different barrier areas but with different barrier properties, e.g., different oxide thicknesses, are formed in a single patterning step and deposition/barrier formation sequence. The deposition/barrier formation sequence can include at least three deposition steps that are each separated by a barrier formation step. Multiple discrete Josephson junctions with different properties can be defined a priori through the engineered design of the patterning features in the resist stack and by a plurality of pre-determined deposition tilt angles and azimuthal rotation angles. By selecting these angles and resist thicknesses, along with standard Josephson junction fabrication parameters, such as the metal thickness and oxidation levels, multiple discrete Josephson junctions with different properties can be formed in the same process with more than one target attribute, e.g., different resistances.

As shown in FIG. 5C, three depositions can be performed to make two Manhattan junctions. In some embodiments, the superconducting layer includes aluminum. The resist opening patterns are designed such that the depositions at the pre-determined tilt angles only reach the substrate surface when they are substantially parallel to the resist channels. The first deposition, i.e., the deposition of SC1 510, is performed at zero azimuthal angle and forms two metal structures on the surface corresponding to the parallel resist channels. At this stage, the first superconducting layer, SC1, 510 is not deposited in the perpendicular channels.

In some embodiments, the SC1 510 is then oxidized to form an oxide tunnel barrier to be used for one of the discrete Josephson junctions. The sample is rotated azimuthally by 90 degrees for the second deposition, i.e., the deposition of SC2 520. The SC2 520 forms a junction with the SC1 510, by utilizing the oxide formed in the first oxidation as the tunnel barrier. Subsequently, the SC2 520 is oxidized to form a second oxide barrier that will be used for the second discrete Josephson junction. Finally, the sample is rotated azimuthally again by 90 degrees for the third deposition, i.e., deposition of SC3 530. The deposition of SC3 530 forms a junction with SC2 520, by utilizing the oxide formed in the second oxidation step as the tunnel barrier. As such, the resist patterns and deposition angles allow multiple junctions to be fabricated in a single sequence with independently defined tunnel barrier oxides and different properties.

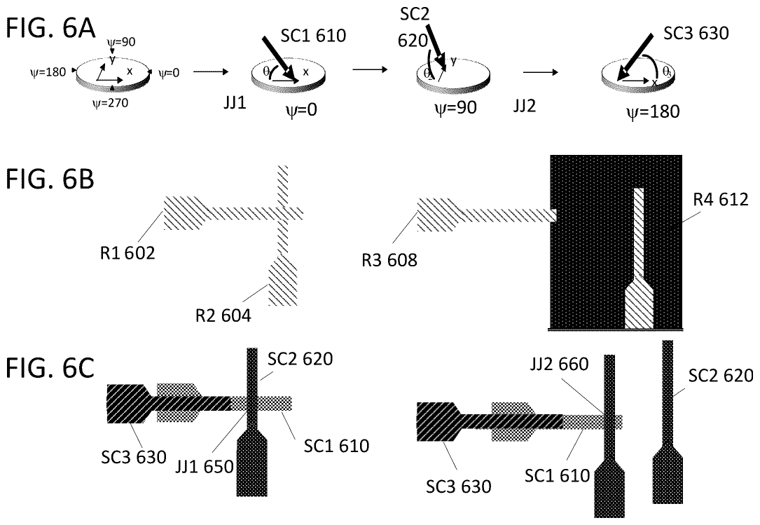

FIGS. 6A-6C illustrate an exemplary process of making two Josephson junctions in a single vacuum step, in accordance with some embodiments. For example, two Josephson junctions with three depositions are formed by creating a resist pattern and choosing angles to form one Manhattan junction and one Dolan bridge junction during a single vacuum process. FIG. 6A illustrates the sequence of angles used in this process. As shown, the deposition of SC1 610 is carried out parallel to the first resist channel, for deposition of SC2 620, the sample rotated azimuthally by 90 degrees. For the third deposition, i.e., deposition of SC3 630, the sample is rotated another 90 degrees, thus 180 degrees compared to the first deposition. FIG. 6B illustrates an outline of the openings made in the resist layers. These two shapes are for junctions with potentially different oxidations steps and junction resistances. FIG. 6C illustrates a schematic of the metal structures formed for the two resist openings at the two angles and is described in more detail below. The Manhattan-type junction JJ1 650 is formed where the SC1 610 and SC2 620 features cross (as defined by the two resist openings R1 602 and R2 604). The Dolan bridge-type junction, JJ2 660, is formed where the SC1 610 and SC3 630 features cross (as defined by the two resist openings R3 608 and R4 612).

In some embodiments, the first superconducting layer, SC1 610, the second superconducting layer SC2 620, and the third superconducting layer SC3 630 are made of aluminum. The quantum computing device as shown in FIG. 6C demonstrates a Manhattan-style Josephson junction, JJ1, 650, and a Dolan bridge-style junction, JJ2, 660, formed in the same process sequence. In order to fabricate the JJ1 650, the resist opening patterns are designed such that depositions at the tilt angles reach the substrate surface when parallel to the channels. In order to fabricate JJ2 660, the deposition reaching the substrate is defined by the placement of the openings and undercut below the resist bridge. The first deposition, i.e., the deposition of SC1 610, is performed at zero azimuthal angle, which forms two SC1 metal structures that will become the base electrodes for both JJ1 650 and JJ2 660. In some embodiments, SC1 610 is not deposited in the perpendicular channels. The SC1 610 is then oxidized to form an oxide tunnel barrier for one of the discrete Josephson junctions. In an embodiment, the sample is rotated 90 degrees azimuthally for the second deposition, i.e., the deposition of SC2 620. As shown in FIG. 6C, SC2 620 overlaps SC1 610 to form the Manhattan junction, i.e., JJ1, 650, by using the oxide from the first deposition as the tunnel barrier.

In some embodiments, SC1 610 is further oxidized to create a thicker oxide tunnel barrier for the second discrete junction, i.e., JJ2 660, which is a Dolan bridge design. Once another 90-degree rotation takes place, the third deposition, i.e., the deposition of SC3 630, reaches the substrate under the Dolan bridge resist. As shown in FIG. 6C, SC3 630 overlaps SC1 610 to form the Dolan bridge, i.e., JJ2 660, by using the thicker oxide from the second oxidation as the tunnel barrier. As such, a combination of Manhattan and Dolan bridge junctions can be fabricated in a single process sequence with independently defined tunnel barrier oxides. It should be noted that, although, the formation of the barrier is referred to as an oxidation of the superconducting layers, it can be considered more broadly as any tunnel barrier formation approach that may include oxidation, nitridation, exposure to reactive gas, etc. In addition, different barrier formation approaches can be applied after each of the deposition of the superconducting layers. Further, in some embodiments, the superconducting layers can be the same materials with same thickness, or different thicknesses. In some embodiments, the superconducting layers can be made of different superconductor materials and may have multiple layers. Even further, the Josephson junctions can be utilized in any superconductor device and may be components of a squid loop.

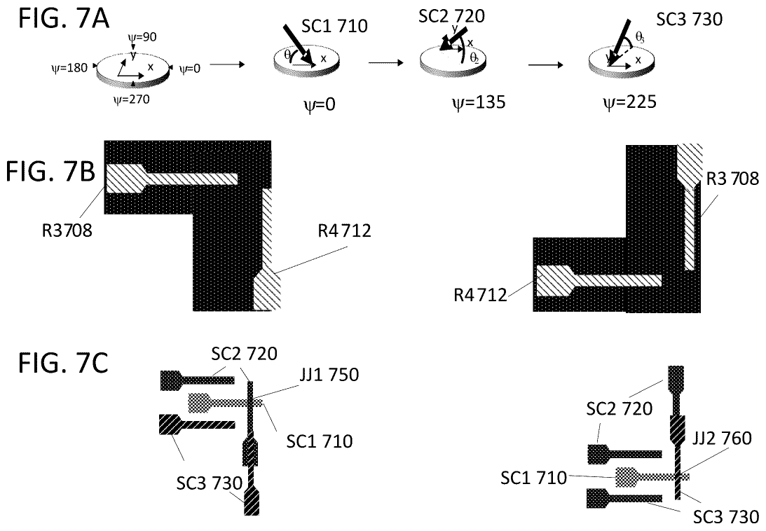

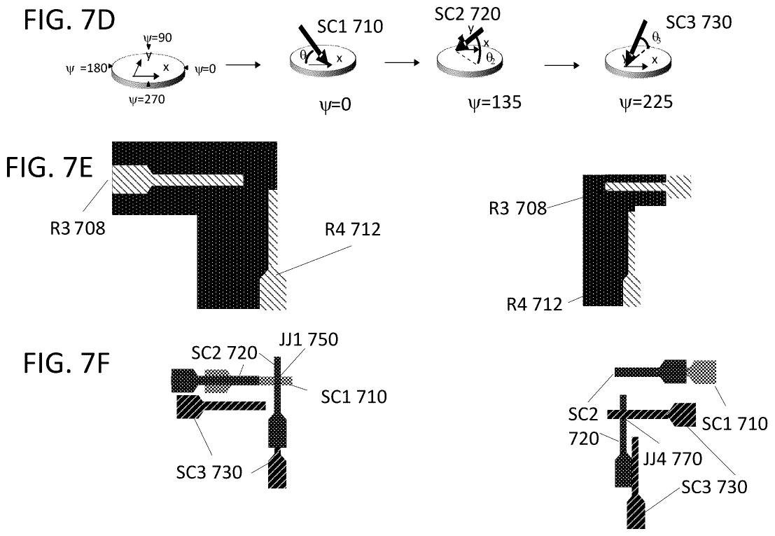

FIGS. 7A-7F illustrate the processes of making two Josephson junctions in a single vacuum step, in accordance with some embodiments. In some embodiments, discrete Josephson junctions with multiple depositions are fabricated by forming a resist pattern and choosing angles to form two Dolan bridge junctions during a single vacuum process. As depicted in FIGS. 7A-7C, two discrete Josephson junctions with the same or different barrier areas, but with different barrier properties, are formed via a single patterning and deposition sequence. The Josephson junctions shown in FIGS. 7A-7C are formed using the Dolan bridge approach. Unlike conventional Dolan bridge junctions where just two depositions in azimuthally opposite directions are used to form one junction, in some embodiments of the present disclosure, two independent junctions with targeted resistances are made when and a third deposition at a 45-degree azimuthal angle relative to the 180-degree separation of the first two depositions is added. FIG. 7A illustrates the sequence of angles used in this process with SC2 720 and SC3 730 deposited and azimuthal angles of 135 and 225 degrees, respectively. That is, the deposition of SC1 710 is carried out parallel to the first resist channel, for deposition of SC2 720, the sample rotated azimuthally by 135 degrees. For the third deposition, i.e., deposition of SC3 730, the sample is rotated 225 degrees.

FIG. 7B illustrates an outline of the openings made in the resist layers, i.e., R3 708 and R4 712. These two shapes are for junctions with potentially different oxidations steps and junction resistances. These two shapes are for junctions with potentially different oxidations steps and junction resistances. FIG. 7C illustrates a schematic of the metal structures formed for the two resist openings at the two angles and is described in more detail below. The junctions are formed where the SC features cross, i.e., JJ1 750 is formed where SC1 710 and SC2 720 cross while JJ2 760 is formed where SC1 710 and SC3 730 cross.

In some embodiments, the two discrete Josephson junctions illustrated in FIGS. 7A-7C are formed by depositing the second superconducting layer, SC2, 720 at +45-degree rotation and the third superconducting layer, SC3, 730 at −45-degree rotation relative to the direction of the first superconducting layer, SC1, 710. In the case of the first junction, JJ1, 750, SC2 720 overlaps SC1 710, while in case of the second junction, JJ2, 760, SC1 710 overlaps SC3 730. As described earlier, the tunnel barriers are created by independent oxidations. In some embodiments, the first oxidation forms the barrier for the first junction, while the sum of two oxidations forms the barrier for the second discrete junction.

While the first Josephson junction illustrated in FIGS. 7D-7F is formed in the same manner as shown in FIGS. 7A-7C, the second junction, JJ4, 770 is formed by the overlap of SC2 720 and SC3 730, without involving SC1 710. In such embodiments, the oxidation to form the tunnel barrier occurs after the deposition of the SC2 720.

FIG. 7D illustrates the sequence of angles used in this process with SC2 720 and SC3 730 deposited and azimuthal angles of 180 and 225 degrees, respectively. That is, the deposition of SC1 710 is carried out parallel to the first resist channel, for deposition of SC2 720, the sample rotated azimuthally by 135 degrees. For the third deposition, i.e., deposition of SC3 730, the sample is rotated 225 degrees. FIG. 7E illustrates an outline of the openings made in the resist layers, i.e., R3 708 and R4 712. These two shapes are for junctions with potentially different oxidations steps and junction resistances. These two shapes are for junctions with potentially different oxidations steps and junction resistances. FIG. 7F illustrates a schematic of the metal structures formed for the two resist openings at the two angles. In the case of the first junction, JJ1, 750, SC2 720 overlaps SC1 710 (formed where the two resist openings R3 708 and R4 712 cross), which is similar to the first junction described in FIG. 7C. However, the second junction, JJ4, 770 is formed by the overlap of SC2 720 and SC3 730, without involving SC1 710. As described earlier, the tunnel barriers are created by independent oxidations. In some embodiments, the first oxidation forms the barrier for the first junction, while the sum of two oxidations forms the barrier for the second discrete junction.

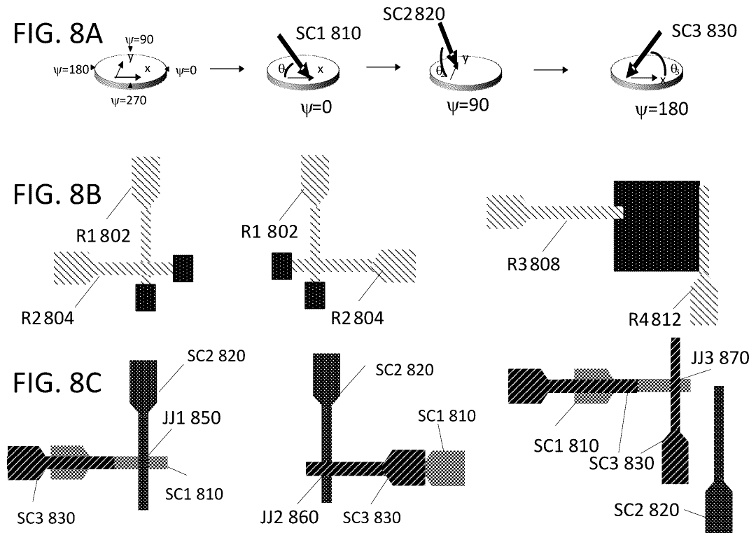

FIGS. 8A-8C illustrate the process of making three Josephson junctions in a single vacuum step, in accordance with some embodiments. In some embodiments, three Josephson junctions with three depositions can be formed in a single vacuum step. The three Josephson junctions can be formed by creating a resist pattern and choosing angles to form two Manhattan junctions and one Dolan bridge junction during a single vacuum process.

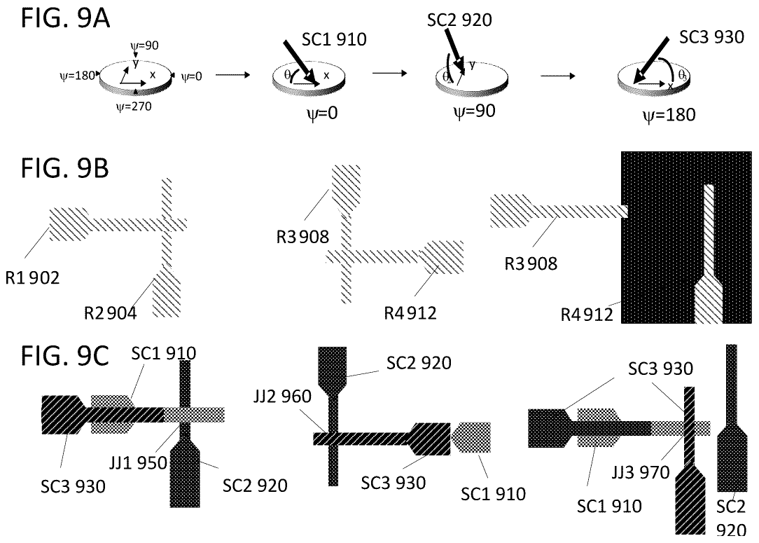

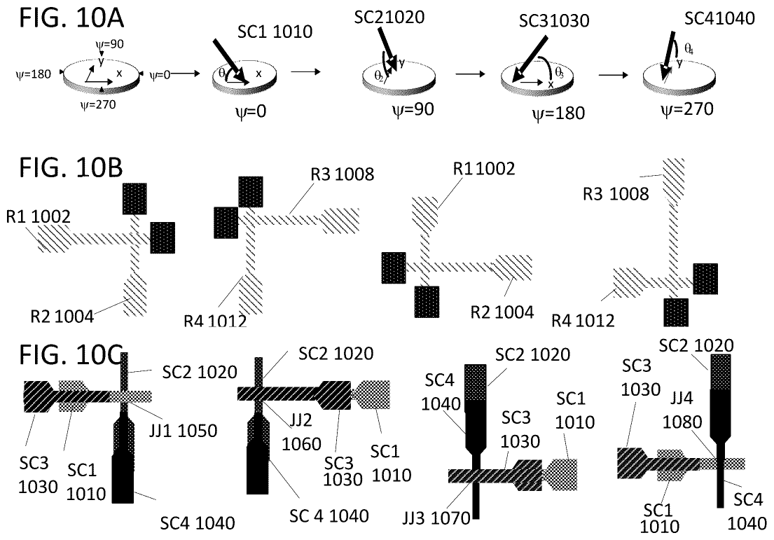

In some embodiments, more than two discrete junctions are fabricated by utilizing appropriate resist patterns and deposition angles. As a non-limiting example, three or four discrete junctions can be made in one vacuum processing step. While FIGS. 8A-8C and 9A-9C illustrate the processes for fabricating three discrete junctions, FIGS. 10A-10C illustrate the processes for fabricating four discrete junctions. Referring to FIGS. 8A-8C, in some embodiments, three distinct resist patterns are used: each of the first two resist patterns includes two resist openings R1 802 and R2 804, and the third resist pattern includes two resist openings R3 808 and R4 812. In some embodiments, the first resist pattern and the second resist pattern are used to form the Manhattan-type junctions, JJ1 850 and JJ2 860. In an embodiment, the R1 802 and R2 804 can be used to form a first junction JJ1, 850 with SC1 810 and SC2 820, and a second junction, JJ2, 860 with SC2 820 and SC3 830.

The third resist pattern is used to form a Dolan-type junction and forms a third junction, JJ3, 870 with SC1 810 and SC3 830. Thus, the JJ1 850 includes a barrier that is formed from the oxidation after SC1 810. Similarly, the JJ2 860 includes a barrier that is formed from the oxidation after SC2 820, and JJ3 870 includes a barrier oxidized by the sum of the oxidation steps after SC1 810 and SC2 820. FIG. 8A illustrates the sequence of angles used with SC2 820 and SC3 830 deposited and azimuthal angles of 90 and 180 degrees, respectively. It should be noted that, SC1 810 is deposited parallel to the resist channel.

FIG. 8B illustrates an outline of the openings made in the resist layers. These three shapes are for junctions with three different oxidations amounts and correspondingly different junction resistances. The Manhattan-type junctions are formed where the two SC features cross as defined by resist openings R1 802 and R2 804 cross, i.e., JJ1 850 and JJ2 860. The Dolan bridge-type junction is formed where the SC1 810 and SC3 830 cross as defined by the resist openings R3 808 and R4 812, i.e., JJ3 870.

FIG. 8C illustrates a schematic of the metal structures formed for the three resist openings at the multiple angles. In the case of the first junction, JJ1, 850, SC2 820 overlaps SC1 810, without involving SC3 830. In the case of the second junction, JJ2, 860, SC2 820 overlaps SC3 830, without involving SC1 810. In the case of the third junction, JJ3, 870, SC2 820 overlaps SC1 810, without involving SC3 830.

Reference is now made to FIGS. 9A-9C, where the processes for fabricating three discrete junctions are illustrated. In some embodiments, three distinct resist patterns are used: the first resist pattern includes two resist openings R1 902 and R2 904, and each of the second and third resist patterns includes two resist openings R3 908 and R4 912. In some embodiments, the first resist pattern is used to form the Manhattan-type junction, JJ1 950. In an embodiment, the R1 902 and R2 904 are used to form the first junction JJ1, 950 with SC1 910 and SC2 920. The second and third resist patterns are used to form two Dolan-type junctions, JJ2 960 and JJ3 970, one with SC2 920 and SC3 930, and another one with SC1 910 and SC3 930. Thus, JJ1 950 includes a barrier that is formed from the oxidation after SC1 910. Similarly, the JJ2 960 includes a barrier oxidized by the sum of the oxidation steps after SC2 920 and SC3 930, and JJ3 970 includes a barrier oxidized by the sum of the oxidation steps after SC1 910 and SC3 930.

FIG. 9A illustrates the sequence of angles used with SC2 920 and SC3 930 deposited and azimuthal angles of 90 and 180 degrees, respectively. It should be noted that, SC1 910 is deposited parallel to the resist channel. FIG. 9B illustrates an outline of the openings made in the resist layers. These three shapes are for junctions with three different oxidations amounts and correspondingly different junction resistances. The Manhattan-type junction is formed where the two resist openings R1 902 and R2 904 cross, i.e., JJ1 950. The Dolan bridge-type junctions are formed where the two resist openings R3 908 and R4 912 will cross, i.e., JJ2 960 and JJ3 970. FIG. 9C illustrates a schematic of the metal structures formed for the three resist layers at the multiple angles. In the case of the first junction, JJ1, 950, SC2 920 overlaps SC1 910, without involving SC3 930. In the case of the second junction, JJ2, 960, SC2 920 overlaps SC3 930, without involving SC1 910. In the case of the third junction, JJ3, 970, SC1 910 overlaps SC3 930, without involving SC2 920.

Reference is now made to FIGS. 10A-10C, which illustrates fabricating four discrete Josephson junctions based on four distinct Manhattan geometries. FIG. 10A illustrates the sequence of angles used in this process with SC2 1020 and SC3 1030 deposited and azimuthal angles of 90 and 180 degrees, respectively. FIG. 10B illustrates an outline of the openings made in the resist layers. These four shapes are for junctions with four different oxidations amounts and correspondingly different junction resistances. The rectangular areas at the tips of the channels are areas where half-bridges (undercuts) are formed by removing the underlayer MMA (methyl methacrylate), while leaving the PMMA (poly(methyl methacrylate). FIG. 10C illustrates a schematic of the metal structures formed for the four resist openings at the multiple angles.

In some embodiments, four distinct resist patterns are used: each of the first and third resist patterns includes two resist openings R1 1002 and R2 1004, and each of the second and fourth resist patterns includes two resist openings R3 1008 and R4 1012. In such embodiments, four superconducting layers can be used. That is, four layers of SC1 1010, SC2 1020, SC3 1030 and SC4 1040 are deposited. To that end, the first and third resist patterns are used to form the Manhattan-type junctions, JJ1 1050 and JJ3 1070. In an embodiment, the R1 1002 and R2 1004 can be used to form the first junction, JJ1, 1050 with SC1 1010 and SC2 1020, and the third junction, JJ3, 1070 with SC3 1030 and SC4 1040. The second and fourth resist patterns are used to form two Dolan-type junctions, JJ2 1060 and JJ4 1080, one with SC2 1020 and SC3 1030, and another one with SC1 1010 and SC4 1040. Thus, JJ1 1050 and JJ3 1070 includes a barrier that is formed from the oxidation after SC1 1010 and SC4 1040, respectively. Similarly, JJ2 1060 includes a barrier oxidized by the sum of the oxidation steps after SC2 1020 and SC3 1030, and JJ4 1080 includes a barrier oxidized by the sum of the oxidation steps after SC1 1010 and SC4 1040.

FIG. 10A illustrates the sequence of angles used with SC2 1020, SC3 1030, and SC4 1040 deposited and azimuthal angles of 90, 180, and 270 degrees, respectively. It should be noted that, SC1 1010 is deposited parallel to the resist channel. FIG. 10B illustrates an outline of the openings made in the resist layers. These four shapes are for junctions with four different oxidations amounts and correspondingly different junction resistances. The Manhattan-type junctions are formed where the two resist openings R1 1002 and R2 1004 cross, i.e., JJ1 1050 and JJ3 1070. The Dolan bridge-type junctions are formed where the two resist openings R3 1008 and R4 1012 cross, i.e., JJ2 1060 and JJ4 1080. FIG. 10C illustrates a schematic of the metal structures formed for the three resist layers at the multiple angles. In the case of the first junction, JJ1, 1050, SC2 1020 overlaps SC1 1010, without involving SC3 1030 and SC4 1040. In the case of the second junction, JJ2, 1060, SC2 1020 overlaps SC3 1030, without involving SC1 1010 and SC4 1040. In the case of the third junction, JJ3, 1070, SC3 1030 overlaps SC4 1040, without involving SC1 1010 and SC2 1020. In the case of the fourth junction, JJ4, 1080, SC4 1040 overlaps SC1 1010, without involving SC2 1020 and SC3 1030.

In some embodiments, four depositions can be performed based on the “four compass directions”: 0 degree, 90 degrees, 180 degrees, and 270 degrees. The openings are such that for both the x- and y-axes, there is a (+) and (−) deposition, with potential electrodes projecting forwards (+) and backwards (−) along the two axes to cover four cases: ++ overlap, +− overlap, −+ overlap, and −− overlap. As such, the first overlap is formed by SC1 1010 and SC2 1020 and includes a barrier oxidized after the deposition of the SC1 1010. The second overlap is formed by SC2 1020 and SC3 1030 and has a barrier oxidized after the deposition of the SC2 1020. The third overlap is formed by SC3 1030 and SC4 1040 and has a barrier oxidized after the deposition of the SC3 1030. Similarly, the fourth overlap is formed from SC1 1010 and SC4 1040 and has a barrier oxidized by the sum of the oxidation steps after SC1 1010, SC2 1020 and SC3 1030.

Table 1 summarizes the exemplary approaches and the fabricated Josephson junctions, in accordance with some embodiments.

TABLE 1

| | | | | | Azimuthal Angle | | |
|---|---|---|---|---|---|---|---|
| | JJ1 | | JJ2 | | (degrees) | | |
| # | Type | Oxidation | Type | Oxidation | SC1 | SC2 | SC3 |
| 1 | Manhattan | post SC1 | Dolan | post SC1 + post SC2 | 0 | 90 | 180 |
| 2 | Manhattan | post SC1 | Manhattan | post SC2 | 0 | 90 | 180 |
| 3 | Dolan | post SC1 | Dolan | post SC1 + post SC2 | 0 | 135 | 225 |
| 4 | Dolan | post SC1 | Dolan | post SC2 | 0 | 180 | 225 |

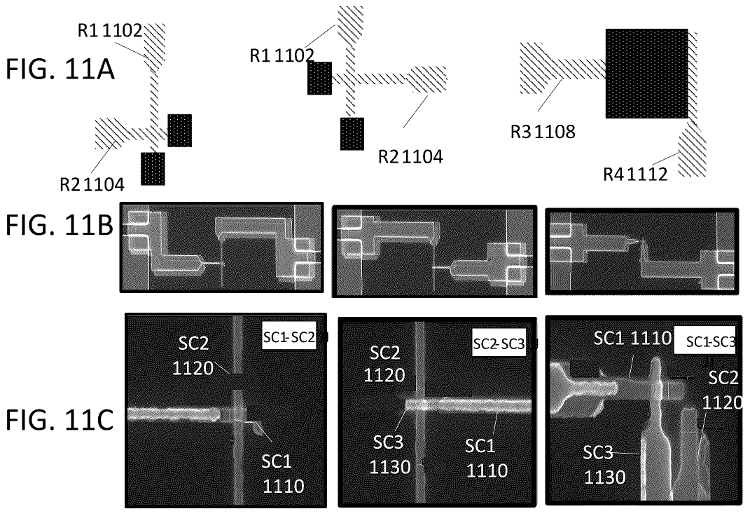

FIGS. 11A-11C illustrate exemplary demonstration images of fabricated Josephson junctions, in accordance with some embodiments. FIG. 11A illustrates the outline of the openings, i.e., R1 1102, R2 1104, R3 1108, and R4 1112, made in the resist patterns of the fabricated junctions, while FIGS. 11B and 11C illustrate scanning electron micrographs of the Josephson junctions having similar sizes. The three shapes shown in FIG. 11A depict junctions with three different oxidations amounts and correspondingly different junction resistances. FIG. 11B illustrates lower magnification images of the three corresponding junctions formed compared to FIG. 11C.

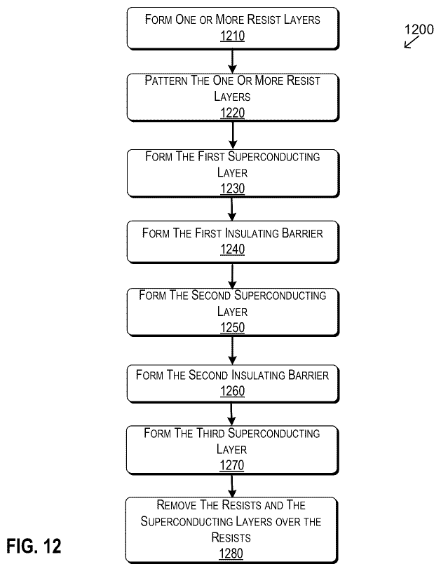

FIG. 12 illustrates a block diagram of method 1200 for fabricating a quantum computing device with discrete Josephson junctions, in accordance with some embodiments. As shown by block 1210, one or more resist layers are formed over a substrate.

As shown by block 1220, the one or more resist layers are patterned to define openings for forming the Josephson junctions.

As shown by block 1230, the first superconducting layer is formed via a first angled deposition.

As shown by block 1240, the first insulating barrier is formed on the first superconducting layer.

As shown by block 1250, the second superconducting layer is formed via a second angled deposition.

As shown by block 1260, the second insulating barrier is formed on the second superconducting layers. In some instances, this second insulating barrier formation may add to the first insulating barrier formation.

As shown by block 1270, the third superconducting layer is formed via a third angled deposition. The first, second and third angled depositions are performed at different azimuthal angles.

As shown by block 1280, the resists and any superconducting layers atop the resists are removed by lift off approaches.

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A device, comprising:
a first superconducting layer over a substrate;
a first insulating barrier over the first superconducting layer;
a second superconducting layer over the first insulating barrier;
a second insulating barrier over the second superconducting layer; and
a third superconducting layer over the second insulating barrier.

2. The device of claim 1, wherein the first insulating barrier and the second insulating barrier have different thicknesses.

3. The device of claim 1, wherein the device includes a plurality of Josephson junctions with more than one resistance area products.

4. The device of claim 1, wherein at least one of the first, second, or third superconducting layers includes aluminum.

5. The device of claim 1, wherein the first, second and third superconducting layers are constructed of a same material.

6. The device of claim 1, wherein at least two of the first, second, and third superconducting layers are constructed of different materials.

7. A method of fabricating Josephson junctions, the method comprising:
patterning one or more resist layers over a substrate to define openings for forming the Josephson junctions;
forming a first superconducting layer via a first angled deposition;
forming a first insulating barrier over the first superconducting layer;
forming a second superconducting layer via a second angled deposition;
forming a second insulating barrier over the second superconducting layer; and
forming a third superconducting layer via a third angled deposition.

8. The method of claim 7, wherein the first and second insulating barriers have different thicknesses.

9. The method of claim 7, wherein the first, second and third angled depositions are performed through a portion of the defined openings.

10. The method of claim 7, further comprising:
fabricating the Josephson junctions with the first and second insulating barriers that have more than one target resistance area based on at least one of: patterns of the defined openings, a formation of the first and second insulating barriers, or a direction of each of the first, second, and third superconducting layers.

11. The method of claim 7, wherein at least one of the first, second, or third superconducting layer includes aluminum.

12. The method of claim 7, wherein forming at least one of the first, second, or third superconducting layer is performed by an electron beam evaporation technique.

13. The method of claim 7, wherein:
forming each of the first and second insulating barriers includes exposure to a pre-determined partial pressure of oxygen gas for a pre-determined time; and
the pre-determined time is used to form the first and second insulating barriers with target thicknesses.

14. The method of claim 7, wherein forming the first and second insulating barriers further comprises oxidizing at least one of the first or second superconducting layers.

15. The method of claim 7, wherein forming the first and second insulating barriers further comprises nitriding at least one of the first or second superconducting layers.

16. The method of claim 7, wherein forming the first and second insulating barriers further comprises exposing at least one of the first or second superconducting layers to a reactive gas.

17. The method of claim 7, wherein the first, second and third superconducting layers are constructed of a same material.

18. The method of claim 7, wherein at least two of the first, second and third superconducting layers are constructed of different materials.

19. A method of fabricating Josephson junctions, the method comprising:
patterning one or more resist layers over a substrate to define openings for forming the Josephson junctions;
forming a first superconducting layer via a first angled depositions through a portion of the openings;
forming a second superconducting layer via second angled depositions through a portion of the openings;
forming a third superconducting layer via a third angled depositions through a portion of the openings; and
forming insulating barriers on the first and second superconducting layers, wherein the insulating barriers have more than one target thickness.

20. The method of claim 19, wherein forming the insulating barriers is performed based on at least one of: i) oxidizing at least one of the first or second superconducting layers, ii) nitriding at least one of the first or second superconducting layers, and iii) exposing of at least one of the first or second superconducting layers to a reactive gas.

21. A method for forming Josephson junctions, the method comprising:
patterning one or more resist layers to define openings for forming the Josephson junctions;
forming a first superconducting layer;
forming a second superconducting layer;
forming a third superconducting layer; and
forming insulating barriers on the first and second superconducting layers, wherein the first, second and third superconducting layers are formed in one vacuum step fabrication process.

22. The method of claim 21, further comprising:
fabricating the Josephson junctions with the insulating barriers that have more than one target resistance area based on at least one of: patterns of the defined openings, a formation of the insulating barriers, or a direction of each of the first, second and third superconducting layers.

23. The method of claim 21, wherein forming the insulating barriers further comprises oxidizing at least one of the first or second superconducting layers.

24. The method of claim 21, wherein forming the insulating barriers further comprises nitriding at least one of the first or second superconducting layers.

25. The method of claim 21, wherein forming the insulating barriers further comprises exposing at least one of the first or second superconducting layers to a reactive gas.
